(19) United States
(12) Patent Application Publication
(10) Pub. No.: US 2026/0273909 A1
(43) Pub. Date: Sep. 17, 2026

(54) LAMINATION APPARATUS, METHOD FOR MANUFACTURING DISPLAY DEVICE USING LAMINATION APPARATUS AND ELECTRONIC DEVICE INCLUDING THE DISPLAY DEVICE

(71) Applicant: Samsung Display Co., LTD., Yongin-si (KR)

(72) Inventors: Gyu Seong SHIM, Yongin-si (KR); Chang Hyung LEE, Yongin-si (KR); Sang Kil WOO, Yongin-si (KR); Jin HYUN, Yongin-si (KR)

(21) Appl. No.: 19/384,257

(22) Filed: Nov. 10, 2025

(30) Foreign Application Priority Data
Mar. 11, 2025 (KR) 10-2025-0031157

(51) Int. Cl. B32B 37/00; H05K 5/02; H05K 5/03

(52) U.S. Cl. CPC B32B 37/0053; H05K 5/0247; H05K 5/03; B32B 2457/202; B32B 2457/206

(57) ABSTRACT

A lamination apparatus includes a fixed stage supporting a cover window, a moving stage supporting a display panel and moving along the fixed stage, a main roller connected to the moving stage, rotating in accordance with the movement of the moving stage and pressurizing the display panel against the cover window, and a guide roller rotating in accordance with the rotation of the main roller in contact with at least a portion of the main roller, and moving in a longitudinal direction of the main roller.

This application claims priority from Korean Patent Application No. 10-2025-0031157, filed on Mar. 11, 2025, and all the benefits accruing therefrom under 35 U.S.C. 119, the content of which in its entirety is herein incorporated by reference.

### BACKGROUND

### 1. Field

The disclosure relates to a lamination apparatus, a method for manufacturing a display device using the lamination apparatus, and an electronic device including the display device.

### 2. Description of the Related Art

With the advancement of multimedia, importance of display devices continues to increase. In response to this trend, various types of display devices such as an organic light-emitting display (“OLED”) device and a liquid crystal display (“LCD”) device are being used. Such display devices continue to diversify in their application examples based on various mobile electronic devices, e.g., portable electronic devices such as smart phones, smart watches and tablet personal computers (“PCs”).

The display device includes a display panel that displays an image and a cover window that is bonded to the display panel to protect the display panel. The cover window is bonded to the display panel by an adhesive material interposed between the display panel and the cover window.

Bonding of the display panel and the cover window may be performed by a pressurizing method using a lamination apparatus.

### SUMMARY

A feature of the disclosure is to provide a lamination apparatus capable of preventing poor bonding between a cover window and a display panel, a method for manufacturing a display device, and an electronic device manufactured using the lamination apparatus.

The features of the disclosure are not limited to those mentioned above and additional features of the disclosure, which are not mentioned herein, will be clearly understood by those skilled in the art from the following description of the disclosure.

In an embodiment of the disclosure, a lamination apparatus includes a fixed stage supporting a cover window, a moving stage supporting a display panel and moving along the fixed stage, a main roller connected to the moving stage, rotating in accordance with the movement of the moving stage and pressurizing the display panel against the cover window, and a guide roller rotating in accordance with the rotation of the main roller in contact with at least a portion of the main roller, and moving in a longitudinal direction of the main roller.

In an embodiment, the lamination apparatus further includes a support member connected to the moving stage, rotatably supporting a rotation shaft of the main roller and a rotation shaft of the guide roller, and a driving member moving the guide roller.

In an embodiment, the rotation shaft of the main roller and the rotation shaft of the guide roller are arranged to be parallel with each other.

In an embodiment, the driving member moves the guide roller along the rotation shaft of the guide roller.

In an embodiment, a moving speed of the guide roller is the same as a moving speed of the moving stage.

In an embodiment, when the display panel rotates in a horizontal direction in a state of being supported by the moving stage, all areas of the display panel are arranged on the moving stage.

In an embodiment, a length of the guide roller is shorter than a length of the main roller.

In an embodiment, a diameter of the main roller is less than a diameter of the guide roller.

In an embodiment, the guide roller moves along the longitudinal direction of the main roller to overlap the display panel pressurized against the cover window by the main roller.

In an embodiment, an upper end of an outer circumference of the main roller and an upper surface of the moving stage are disposed on a same virtual plane.

In an embodiment, a rotation speed of the main roller is faster than a rotation speed of the guide roller.

In an embodiment of the disclosure, a method for manufacturing a display device includes arranging a cover window on a fixed stage, arranging a display panel on an upper surface of a moving stage so that a portion of the display panel is disposed on a main roller, arranging the moving stage so that a portion of the display panel disposed on the main roller contacts the cover window, rotating the main roller by movement of the moving stage along the fixed stage to pressurize the cover window and the display panel, and moving a guide roller in a longitudinal direction of the main roller.

In an embodiment, the display panel includes a plurality of sides, and when arranging the display panel on the upper surface of the moving stage so that a portion of the display panel is disposed on the main roller, a portion of the display panel disposed on the main roller is one of the plurality of sides of the display panel.

In an embodiment, one side of the display panel disposed on the main roller is disposed to be parallel with the longitudinal direction of the main roller.

In an embodiment, a moving speed of the guide roller is the same as a moving speed of the moving stage.

In an embodiment, the guide roller rotates in accordance with the rotation of the main roller in contact with at least a portion of the main roller, and a rotation speed of the main roller is faster than a rotation speed of the guide roller.

In an embodiment, a diameter of the main roller is less than a diameter of the guide roller.

In an embodiment, the moving the guide roller in the longitudinal direction of the main roller includes moving the guide roller along the longitudinal direction of the main roller to overlap the display panel pressurized against the cover window by the main roller.

In an embodiment of the disclosure, an electronic device includes a display device manufactured by a lamination apparatus, the lamination apparatus includes a fixed stage supporting a cover window, a moving stage supporting a display panel and moving along the fixed stage, a main roller connected to the moving stage, rotating in accordance with the movement of the moving stage and pressurizing the display panel against the cover window, and a guide roller rotating in accordance with the rotation of the main roller in contact with at least a portion of the main roller, and moving in a longitudinal direction of the main roller.

In an embodiment, the electronic device further includes at least one of a processor, a memory in which one or more data of the display device and the processor are stored, or a power module supplying a power source to the display device, the processor, and the memory.

In an embodiment, in the lamination apparatus, the method for manufacturing a display device, and the electronic device manufactured using the lamination apparatus according to the disclosure, a guide roller that contacts a main roller pressurizing a cover window and a display panel may move along a longitudinal direction of the main roller to overlap the display panel, thereby preventing poor bonding between the cover window and the display panel.

The effects in the embodiments of the disclosure are not limited to those mentioned above and more various effects are included in the following description of the disclosure.

### BRIEF DESCRIPTION OF THE DRAWINGS

The above and other advantages and features of the disclosure will become more apparent by describing in detail embodiments thereof with reference to the attached drawings, in which:

FIG. 1 is a plan view illustrating an embodiment of a display device;

FIG. 2 is a cross-sectional view taken along line A-A′ of FIG. 1;

FIG. 3 is a cross-sectional view schematically illustrating a display panel of FIG. 2;

FIG. 4 is a schematic view illustrating an embodiment of a lamination apparatus according to the disclosure;

FIG. 5 is a side view illustrating a moving stage, a main roller, a guide roller, a support member, and a driving member of FIG. 4;

FIG. 6 is a plan view of FIG. 5;

FIG. 7 is a front view of FIG. 5;

FIG. 8 is a schematic view illustrating an embodiment of a lamination apparatus in an embodiment of the disclosure in a state that a cover window and a display panel start to be pressurized;

FIG. 9 is a plan view illustrating a moving stage, a main roller, a guide roller, a support member, and a driving member of FIG. 8;

FIG. 10 is a front view of FIG. 9;

FIG. 11 is a schematic view illustrating an embodiment of a lamination apparatus in an embodiment of the disclosure in a state that a cover window and a display panel are pressurized;

FIG. 12 is a plan view illustrating a moving stage, a main roller, a guide roller, a support member, and a driving member of FIG. 11;

FIG. 13 is a front view of FIG. 12;

FIG. 14 is a schematic view illustrating an embodiment of a lamination apparatus in an embodiment of the disclosure in a state that pressurization of a cover window and a display panel is terminated;

FIG. 15 is a plan view illustrating a moving stage, a main roller, a guide roller, a support member, and a driving member of FIG. 14;

FIG. 16 is a front view of FIG. 15;

FIG. 17 is a block diagram illustrating an embodiment of an electronic device; and

FIG. 18 illustrates schematic diagrams of embodiments of electronic devices.

### DETAILED DESCRIPTION OF THE DISCLOSURE

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The drawing figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments may be practiced individually or in combination.

Hereinafter, embodiments of the disclosure will be described in detail with reference to the accompanying drawings.

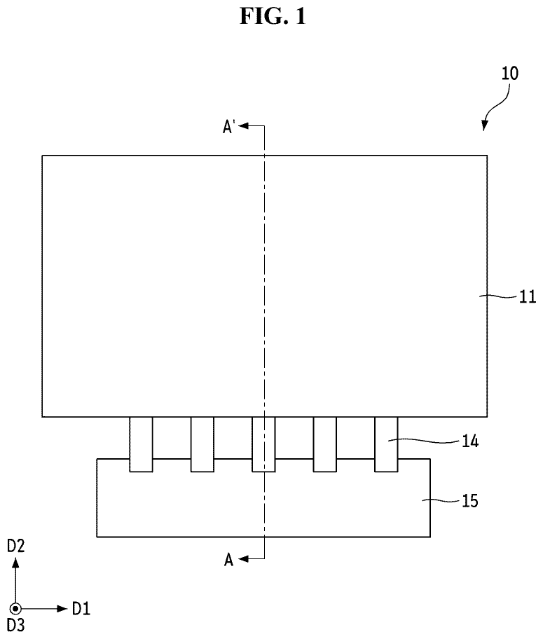

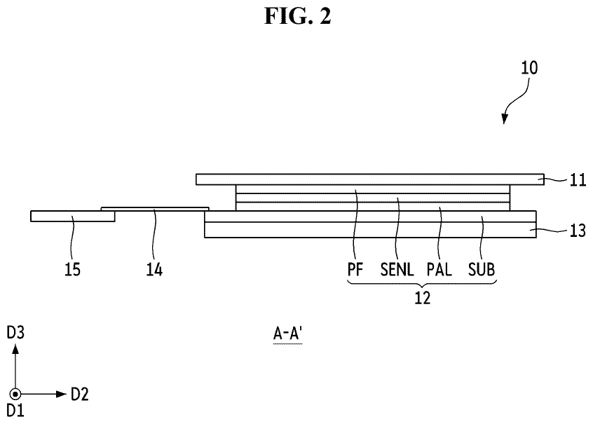

FIG. 1 is a plan view illustrating an embodiment of a display device. FIG. 2 is a cross-sectional view taken along line A-A′ of FIG. 1.

Referring to FIGS. 1 and 2, a display device 10 in an embodiment may include a cover window 11, a display panel 12, a panel lower member 13, a connection member 14, and a driving circuit board 15.

The cover window 11 may include a material having relatively high light transmittance. The cover window 11 may include a polymer resin such as polyimide or glass. The cover window 11 may be attached onto a polarizing film PF, which is to be described later, of the display panel 12 by an adhesive member such as an optically clear adhesive (“OCA”) film.

The display panel 12 may be disposed below the cover window 11. The display panel 12 may have a quadrangular, e.g., rectangular planar shape having long sides in a first direction D1 and short sides in a second direction D2. In the display panel 12, a corner at which the long side in the first direction D1 and the short side in the second direction D2 meet may be formed at a right angle, or may be rounded to have a curvature. The display panel 12 may have a planar shape such as another quadrangle other than a quadrangular shape, e.g., rectangular shape, a polygonal shape other than the quadrangle, a circular shape, an oval shape or an atypical shape.

The display panel 12 may include a display area in which a plurality of light emission areas for emitting light are arranged and a non-display area disposed around the display area. The non-display area may be disposed to surround the display area. A plurality of display pads may be arranged in the non-display area at an edge of one side of the display panel 12.

The display panel 12 may include a substrate SUB, a display unit PAL, a sensor unit SENL, and a polarizing film PF.

The substrate SUB may include or consist of an insulating material such as glass, quartz and polymer resin. The substrate SUB may be a rigid substrate, or a flexible substrate capable of being subjected to bending, folding, rolling, etc.

The display unit PAL may be disposed on the substrate SUB. The display unit PAL may be a layer including a plurality of light emission areas for emitting light. The display unit PAL may include a buffer film, a thin film transistor layer in which thin film transistors are arranged, a light-emitting element layer for emitting light, and an encapsulation layer for encapsulating the light-emitting element layer.

The sensor unit SENL may be disposed on the display unit PAL. The sensor unit SENL includes sensor electrodes, and may be a layer for sensing whether there is a user's touch.

The polarizing film PF may be disposed on the sensor unit SENL. The polarizing film PF may serve to prevent image visibility of the display panel 12 from being deteriorated due to reflection of external light. The polarizing film PF may include a linearly polarizing plate and a phase delay film such as a λ/4 (quarter-wave) plate. The phase delay film may be disposed on the sensor unit SENL, and the linearly polarizing plate may be disposed on the phase delay film. The cover window 11 may be disposed on the polarizing film PF.

The panel lower member 13 may be disposed below the substrate SUB. The panel lower member 13 may be attached to a lower surface of the substrate SUB through an adhesive member. The adhesive member may be a pressure sensitive adhesive (“PSA”). The panel lower member 13 may include at least one of a light-absorbing member for absorbing light incident from the outside, a buffer member for absorbing external impact, or a heat dissipation member for efficiently emitting heat of the display panel 12.

The light-absorbing member may be disposed below the substrate SUB. The light-absorbing member prevents transmission of light to prevent components arranged below the light-absorbing member, e.g., the driving circuit board 15 or the like, from being recognized from an upper portion of the display panel 12. The light-absorbing member may include a light-absorbing material such as a black pigment or a black dye.

The buffer member may be disposed below the light-absorbing member. The buffer member absorbs external impact to prevent the display panel 12 from being damaged. The buffer member may include a single layer or a plurality of layers. In an embodiment, the buffer member may include or consist of a polymer resin such as polyurethane, polycarbonate, polypropylene, or polyethylene, or may include an elastic material such as rubber, a urethane-based material, or a sponge formed by foaming an acrylic-based material, for example.

The heat dissipation member may be disposed below the buffer member. The heat dissipation member may include a first heat dissipation layer including graphite, carbon nanotube, or the like, and a second heat dissipation layer including a metal thin film such as copper, nickel, ferrite, or silver, which may shield electromagnetic waves and have excellent thermal conductivity.

The connection member 14 may be connected to the plurality of display pads of the display panel 12 through a conductive adhesive member such as an anisotropic conductive film. As a result, the display panel 12 and the connection member 14 may be electrically connected to each other.

In addition, the connection member 14 may be connected to a plurality of circuit pads of the driving circuit board 15 through a conductive adhesive member such as an anisotropic conductive film. As a result, the connection member 14 and the driving circuit board 15 may be electrically connected to each other.

The connection member 14 may be a flexible printed circuit board or a chip on film.

The driving circuit board 15 may be disposed below the panel lower member 13 when the connection member 14 is bent. The driving circuit board 15 may be a flexible printed circuit board (“FPCB”) that may be bent, a rigid printed circuit board (“PCB”) that is hard and does not bend well, or a composite printed circuit board including both a rigid printed circuit board and a flexible printed circuit board.

The driving circuit board 15 may process a signal converted by a control circuit board (not shown) and transmit the signal to the display panel 12. The driving circuit board 15 may be electrically connected to the display panel 12 by the connection member 14.

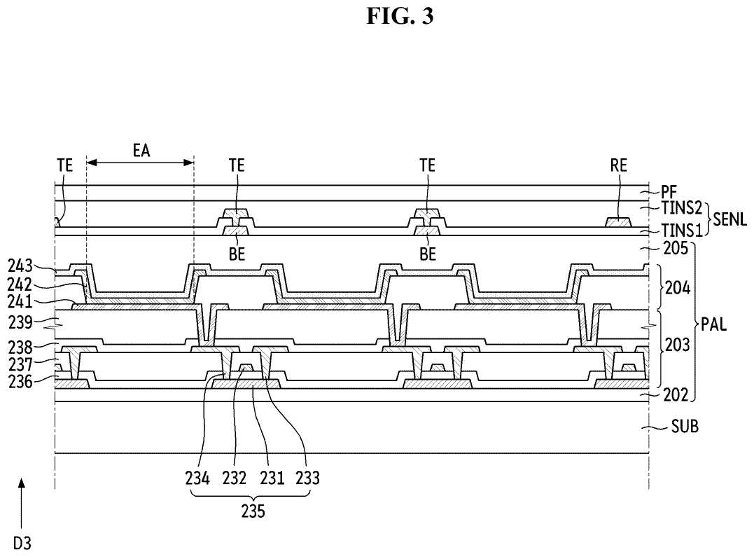

FIG. 3 is a cross-sectional view schematically illustrating the display panel of FIG. 2.

Referring to FIG. 3, the display unit PAL may include a buffer film 202, a thin film transistor layer 203, a light-emitting element layer 204, and an encapsulation layer 205.

The buffer film 202 may be formed on the substrate SUB. The buffer film 202 may be formed on the substrate SUB to protect the thin film transistors 235 and light-emitting elements from moisture permeated through the substrate SUB that is vulnerable to moisture permeation. The buffer film 202 may include a plurality of inorganic layers that are alternately stacked. In an embodiment, the buffer film 202 may include a multi-film in which one or more inorganic films of a silicon oxide film (SiOx), a silicon nitride film (SiNx), and SiON are alternately stacked, for example. In another embodiment, the buffer film 202 may be omitted.

The thin film transistor layer 203 is formed on the buffer film 202. The thin film transistor layer 203 includes thin film transistors 235, a gate insulating film 236, an inter-insulating film 237, a passivation film 238, and an organic film 239.

Each of the thin film transistors 235 includes an active layer 231, a gate electrode 232, a source electrode 233, and a drain electrode 234. Although FIG. 3 illustrates that the thin film transistor 235 is formed using a top gate mode in which the gate electrode 232 is disposed above the active layer 231, it should be noted that the thin film transistor 235 is not limited thereto. That is, the thin film transistors 235 may be formed in a bottom gate mode in which the gate electrode 232 is disposed below the active layer 231 or a double gate mode in which the gate electrode 232 is disposed above and below the active layer 231.

The active layer 231 is formed on the buffer film 202. The active layer 231 may include a silicon-based semiconductor material or an oxide-based semiconductor material. In an embodiment, the active layer 231 may include polysilicon, amorphous silicon, or oxide semiconductor, for example. A light-blocking layer for blocking external light incident on the active layer 231 may be formed between the buffer film 202 and the active layer 231.

The gate insulating film 236 may be formed on the active layer 231. The gate insulating film 236 may include an inorganic film, e.g., a silicon oxide film (SiOx), a silicon nitride film (SiNx), or their multi-film.

The gate electrode 232 may be formed on the gate insulating film 236. The gate electrode 232 and a gate line may be formed as a single layer or multi-layer including or consisting of any one of molybdenum (Mo), aluminum (Al), chromium (Cr), gold (Au), titanium (Ti), nickel (Ni), neodymium (Nd) and copper (Cu), or their alloy.

The inter-insulating film 237 may be formed on the gate electrode 232 and the gate line. The inter-insulating film 237 may include an inorganic film, e.g., a silicon oxide film (SiOx), a silicon nitride film (SiNx), or their multi-film.

The source electrode 233 and the drain electrode 234 may be formed on the inter-insulating film 237. Each of the source electrode 233 and the drain electrode 234 may be connected to the active layer 231 through a contact hole passing through the gate insulating film 236 and the inter-insulating film 237. The source electrode 233 and the drain electrode 234 may be formed as a single layer or multi-layer including or consisting of molybdenum (Mo), aluminum (Al), chromium (Cr), gold (Au), titanium (Ti), nickel (Ni), neodymium (Nd) and copper (Cu), or their alloy.

The passivation film 238 for insulating the thin film transistor 235 may be formed on the source electrode 233 and the drain electrode 234. The passivation film 238 may include an inorganic film, e.g., a silicon oxide film (SiOx), a silicon nitride film (SiNx), or their multi-film.

The organic film 239 for planarizing a step difference due to the thin film transistor 235 may be formed on the passivation film 238. The organic film 239 may include an organic film such as an acrylic resin, an epoxy resin, a phenolic resin, a polyamide resin, or a polyimide resin.

The light-emitting element layer 204 is formed on the thin film transistor layer 203. The light-emitting element layer 204 includes light-emitting elements and a bank.

The light-emitting elements and the bank are formed on the organic film 239. It is illustrated that the light-emitting element is an organic light-emitting device that includes an anode electrode 241, light-emitting layers 242, and a cathode electrode 243.

The anode electrode 241 may be formed on the organic film 239. The anode electrode 241 may be connected to the source electrode 233 of the thin film transistor 235 through a contact hole passing through the passivation film 238 and the organic film 239.

The bank may be formed to cover an edge of the anode electrode 241 on the organic film 239, thereby partitioning light emission areas EA of pixels. That is, the bank serves to define the light emission areas EA of the pixels. Each of the pixels represents an area in which the anode electrode 241, the light-emitting layer 242 and the cathode electrode 243 are sequentially stacked to combine holes from the anode electrode 241 with electrons from the cathode electrode 243 in the light-emitting layer 242, thereby emitting light.

The light-emitting layers 242 are formed on the anode electrode 241 and the bank. The light-emitting layer 242 may be an organic light-emitting layer. The light-emitting layer 242 may emit one of red light, green light and blue light. In an alternative embodiment, the light-emitting layer 242 may be a white light-emitting layer for emitting white light, and in this case, the light-emitting layer 242 may have a structure in which a red light-emitting layer, a green light-emitting layer and a blue light-emitting layer are stacked, and may be a common layer commonly formed in the pixels. In this case, the display panel 12 may further include a separate color filter for displaying red, green and blue.

The light-emitting layer 242 may include a hole transporting layer, a light-emitting layer and an electron transporting layer. In addition, the light-emitting layer 242 may be formed in a tandem structure of two or more stacks, and in this case, a charge generating layer may be formed between the stacks.

The cathode electrode 243 is formed on the light-emitting layer 242. The cathode electrode 243 may be formed to cover the light-emitting layer 242. The cathode electrode 243 may be a common layer commonly formed in the pixels.

When the light-emitting element layer 204 is formed in a top emission mode in which light is emitted in an upward direction, the anode electrode 241 may include a metal material having relatively high reflectance, such as a stacked structure (Ti/Al/Ti) of aluminum (Al) and titanium (Ti), a stacked structure (ITO/Al/ITO) of aluminum (Al) and indium tin oxide (“ITO”), APC alloy and a stacked structure (ITO/APC/ITO) of APC alloy and ITO. The APC alloy is an alloy of silver (Ag), palladium (Pd) and copper (Cu). The cathode electrode 243 may include a transparent conductive material (“TCO”) such as ITO and indium zinc oxide (“IZO”), which may transmit light, or a semi-transmissive conductive material such as magnesium (Mg), silver (Ag) or an alloy of magnesium (Mg) and silver (Ag). When the cathode electrode 243 includes a semi-transmissive conductive material, light emission efficiency may be increased by a micro cavity.

When the light-emitting element layer 204 is formed in a bottom emission mode in which light is emitted in a downward direction, the anode electrode 241 may include a TCO such as ITO and IZO, or a semi-transmissive conductive material such as magnesium (Mg), silver (Ag) or an alloy of magnesium (Mg) and silver (Ag). The cathode electrode 243 may include a metal material having relatively high reflectance, such as a stacked structure (Ti/Al/Ti) of aluminum (Al) and titanium (Ti), a stacked structure (ITO/Al/ITO) of aluminum (Al) and ITO, APC alloy, and a stacked structure (ITO/APC/ITO) of APC alloy and ITO. When the anode electrode 241 includes a semi-transmissive conductive material, light emission efficiency may be increased by a micro cavity.

The encapsulation layer 205 is formed on the light-emitting element layer 204. The encapsulation layer 205 serves to prevent permeation of oxygen or moisture into the light-emitting layer 242 and the cathode electrode 243. To this end, the encapsulation layer 205 may include at least one inorganic film. The inorganic film may include silicon nitride, aluminum nitride, zirconium nitride, titanium nitride, hafnium nitride, tantalum nitride, silicon oxide, aluminum oxide or titanium oxide. Also, the encapsulation layer 205 may further include at least one organic film. The organic film may be formed to have a sufficient thickness to prevent particles from being permeated into the light-emitting layer 242 and the cathode electrode 243 by passing through the encapsulation layer 205. The organic film may include any one of epoxy, acrylate and urethane acrylate.

The sensor unit SENL may be formed on the encapsulation layer 205. When the sensor unit SENL is formed directly on the encapsulation layer 205, there is an advantage in that a thickness of the display device 10 may be reduced as compared with the case that a separate touch panel is attached onto the encapsulation layer 205.

The sensor unit SENL may include sensor electrodes for sensing a user's touch in a capacitance manner and touch lines connecting pads with the sensor electrodes. In an embodiment, the sensor unit SENL may sense the user's touch in a self-capacitance manner or a mutual capacitance manner, for example. The description in FIG. 3 has been based on that the sensor unit SENL is formed in a mutual capacitance manner of a two-layer that includes the driving electrodes TE, the sensing electrodes RE, and the connection portions BE connecting the driving electrodes TE.

The connection portions BE may be formed on the encapsulation layer 205. The connection portions BE may include a stacked structure (Ti/Al/Ti) of aluminum and titanium, a stacked structure (ITO/Al/ITO) of aluminum (Al) and ITO, APC alloy, and a stacked structure (ITO/APC/ITO) of APC alloy and ITO, but are not limited thereto. In an embodiment, the connection portions BE may include a single layer of molybdenum (Mo), titanium (Ti), copper (Cu), aluminum (Al) or ITO, for example.

A first sensing insulating film TINS1 is formed on the connection portions BE. The first sensing insulating film TINS1 may include an inorganic film, e.g., a silicon nitride film, a silicon oxynitride film, a silicon oxide film, a titanium oxide film or an aluminum oxide film.

The driving electrodes TE and the sensing electrodes RE may be formed on the first sensing insulating film TINS1. The driving electrodes TE and the sensing electrodes RE may include a stacked structure (Ti/Al/Ti) of aluminum (Al) and titanium, a stacked structure (ITO/Al/ITO) of aluminum (Al) and ITO, APC alloy, and a stacked structure (ITO/APC/ITO) of APC alloy and ITO, but are not limited thereto. In an embodiment, the driving electrodes TE and the sensing electrodes RE may include a single layer of molybdenum (Mo), titanium (Ti), copper (Cu), aluminum (Al) or ITO, for example.

Contact holes exposing the connection portions BE by passing through the first sensing insulating film TINS1 may be formed in the first sensing insulating film TINS1. The driving electrodes TE may be connected to the connection portions BE through the contact holes.

A second sensing insulating film TINS2 is formed on the driving electrodes TE and the sensing electrodes RE. The second sensing insulating film TINS2 may serve to planarize a step difference caused by the driving electrodes TE, the sensing electrodes RE and the connection portions BE. The second sensing insulating film TINS2 may include an organic film such as an acrylic resin, an epoxy resin, a phenolic resin, a polyamide resin and a polyimide resin.

The connection portions BE connecting the driving electrodes TE next (adjacent) to each other may be disposed on the encapsulation layer 205, and the driving electrodes TE and the sensing electrodes RE may be arranged on the first sensing insulating film TINS1. Therefore, the driving electrodes TE and the sensing electrodes RE may be electrically separated from each other at their intersections, the sensing electrodes RE may be electrically connected to each other in one direction, and the driving electrodes TE may be electrically connected to each other in a remaining (the other) direction.

The polarizing film PF may be disposed on the second sensing insulating film TINS2 to prevent deterioration in image visibility of the display panel 12 due to reflection of external light.

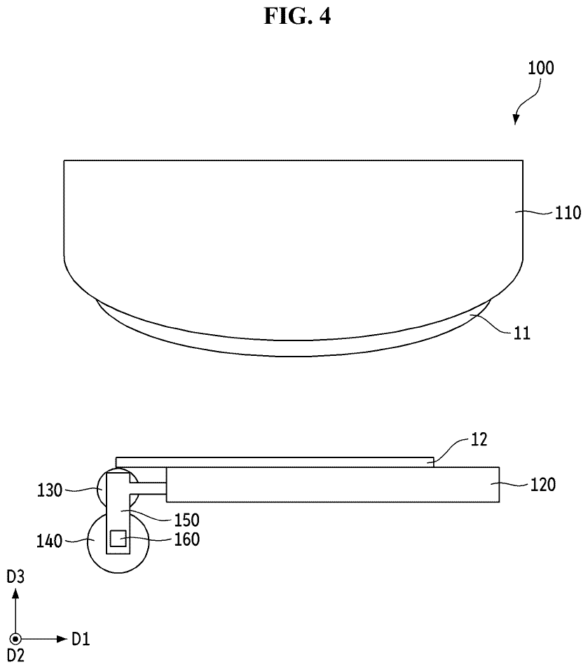

FIG. 4 is a schematic view illustrating an embodiment of a lamination apparatus according to the disclosure.

Referring to FIG. 4, a lamination apparatus 100 in an embodiment of the disclosure may bond the cover window 11 to the display panel 12 of the display device 10. The lamination apparatus 100 may include a fixed stage 110, a moving stage 120, a main roller 130, a guide roller 140, a support member 150, and a driving member 160.

The fixed stage 110 may support the cover window 11. One surface of the fixed stage 110 may be formed in a streamlined shape, and the cover window 11 may be seated on one surface of the fixed stage 110, which is formed in a streamlined shape, and then may be supported by the fixed stage 110. One surface of the fixed stage 110, which is formed in a streamlined shape, may be formed in a lower area of the fixed stage 110. When one surface of the fixed stage 110 is formed in a streamlined shape, the fixed stage 110 may support the cover window 11 of the curved display device. When one surface of the fixed stage 110 is formed as a flat surface, the fixed stage 110 may support the cover window 11 of the flat display device.

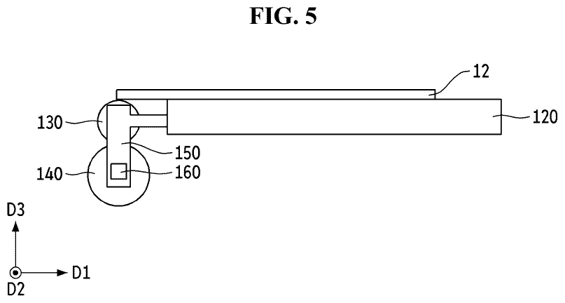

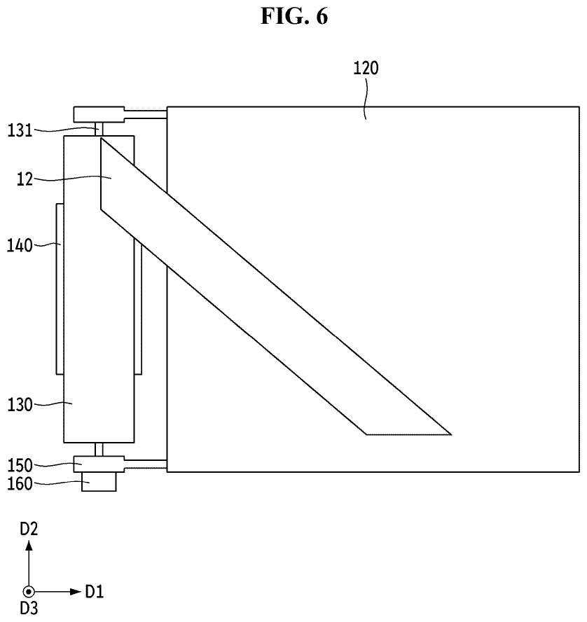

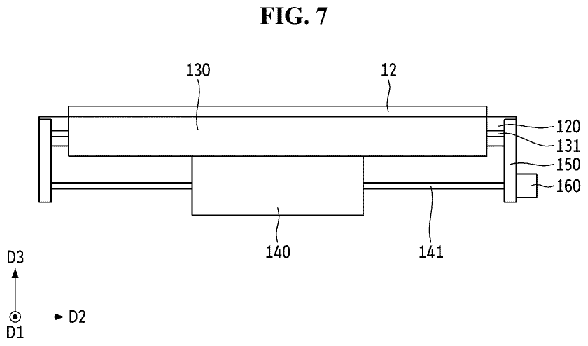

FIG. 5 is a side view illustrating a moving stage, a main roller, a guide roller, a support member, and a driving member of FIG. 4. FIG. 6 is a plan view of FIG. 5. FIG. 7 is a front view of FIG. 5.

Referring to FIGS. 5 to 7, the moving stage 120 may support the display panel 12. The moving stage 120 may be disposed below the fixed stage 110, and the display panel 12 may be seated on an upper surface of the moving stage 120. The upper surface of the moving stage 120 may be disposed to face one surface of the fixed stage 110, which is formed in a streamlined shape. The moving stage 110 may move along one surface of the fixed stage 110 in a state that the cover window 11 and the display panel 12 contact each other.

The moving stage 120 may be formed to have a width in which all areas of the display panel 12 may be disposed inside the moving stage 120. The moving stage 120 may be formed to have a width in which all areas of the display panel 12 may be arranged on the moving stage 120 when the display panel 12 is rotated in a horizontal direction in a state of being seated on the upper surface of the moving stage 120.

The main roller 130 may be connected to the moving stage 120 and thus rotated in accordance with movement of the moving stage 120. The main roller 130 may be rotated around a rotation shaft 131 extended from the center of the main roller 130 in the second direction D2. The main roller 130 may be connected to the moving stage 120 by the support member 150. The main roller 130 may be connected to the moving stage 120 in a direction opposite to the direction in which the moving stage 120 is moved.

The main roller 130 may contact the display panel 12. The main roller 130 may be disposed below the fixed stage 110 so that the display panel 12, which contacts the main roller 130, contacts the cover window 11. In a state that the cover window 11 and the display panel 12 contact each other, the main roller 130 may be rotated in accordance with movement of the moving stage 120 to pressurize the cover window 11 and the display panel 12. The cover window 11 and the display panel 12 may be bonded to each other by pressurization of the main roller 130.

An upper end of an outer circumference of the main roller 130 and the upper surface of the moving stage 120 may be disposed on the same virtual plane. In some embodiments, a virtual horizontal line extended from the upper end of the main roller 130 to the upper surface of the moving stage 120 may be a straight line.

The guide roller 140 may rotate in accordance with rotation of the main roller 130 in contact with at least a portion of the main roller 130. The guide roller 140 may rotate around a rotation shaft 141 extended from the center of the guide roller 140 in the second direction D2. The rotation shaft 141 of the guide roller 140 may be disposed to be parallel with the rotation shaft 131 of the main roller 140. The guide roller 140 may be connected to the moving stage 120 by the support member 150. The guide roller 140 may be disposed to contact at least a portion of the main roller 130 below the main roller 130.

The guide roller 140 may move in a longitudinal direction of the main roller 130. In some embodiments, the guide roller 140 may move in the second direction D2 along the rotation shaft 141 of the guide roller 140. The guide roller 140 may move by the driving member 160 disposed in the support member 150. A moving speed of the guide roller 140 may be the same as a moving speed of the moving stage 120.

A length of the guide roller 140 in the second direction D2 may be shorter than a length of the main roller 130 in the second direction D2. In addition, a diameter of the guide roller 140 may be larger than a diameter of the main roller 130. Since the guide roller 140 rotates by the rotation of the main roller 130 in contact with the main roller 130, when the diameter of the guide roller 140 is larger than the diameter of the main roller 130, a rotation speed of the guide roller 140 may be slower than a rotation speed of the main roller 130. When the rotation speed of the guide roller 140 is slower than the rotation speed of the main roller 130, the guide roller 140 may easily move, and may move more stably.

The guide roller 140 may move along the longitudinal direction of the main roller 130 to always overlap the display panel 12 pressurized against the cover window 11 by the main roller 130. While the main roller 130 pressurizes the display panel 12 against the cover window 11, the main roller 130 may be sagging downward due to its weight. When the main roller 130 is sagging downward, the pressure pressurizing the display panel 12 is lowered, and thus the pressurizing force of the cover window 11 and the display panel 12 is weakened, whereby poor bonding may occur between the cover window 11 and the display panel 12. The guide roller 140 moves along the longitudinal direction of the main roller 130 to overlap the display panel 12 pressurized against the cover window 11, thereby preventing the main roller 130 pressurizing the display panel 12 from sagging, and preventing poor bonding from occurring between the cover window 11 and the display panel 12.

The support member 150 may be connected to the moving stage 120, and may rotatably support the rotation shaft 131 of the main roller 130 and the rotation shaft 141 of the guide roller 140. The support member 150 may be extended from one side (left side of FIG. 5) of the moving stage 120 toward a direction opposite to the moving direction (right side of FIG. 5) of the moving stage 120.

The support member 150 may be provided as a plurality of support members, and the plurality of support members 150 may be arranged to be spaced apart from each other in the second direction D2. Respective sides of the rotation shaft 131 of the main roller 130 and respective sides of the rotation shaft 141 of the guide roller 140 may be rotatably connected to the support members 150 spaced apart from each other in the second direction D2, so that the main roller 130 and the guide roller 140 may rotate.

The driving member 160 may move the guide roller 140. The driving member 160 may be provided as a step motor or a linear motor, which is disposed in the support member 150. The driving member 160 may move the guide roller 140 in the longitudinal direction of the main roller 130. In some embodiments, the driving member 160 may move the guide roller 140 in the second direction D2 along the rotation shaft 141 of the guide roller 140.

The driving member 160 may move the guide roller 140 so that the guide roller 140 overlaps the display panel 12 pressurized against the cover window 11 by the main roller 130. The driving member 160 may move the guide roller 140 so that the moving speed of the moving stage 120 is the same as the moving speed of the guide roller 140.

Hereinafter, a method for manufacturing the display device 10 by the lamination apparatus 100 in an embodiment of the disclosure will be described with reference to the drawings.

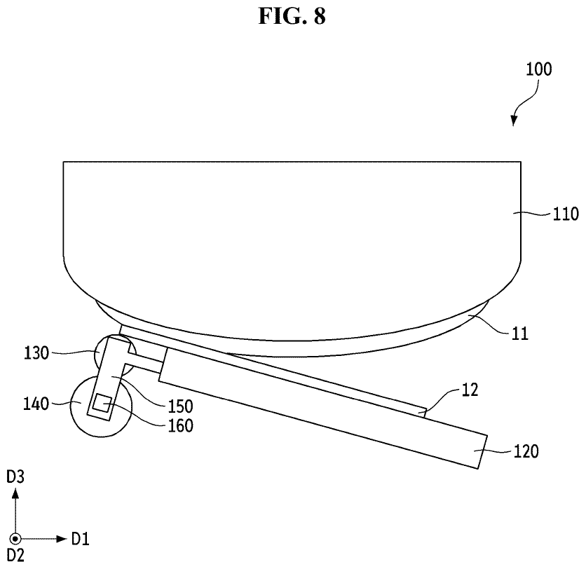

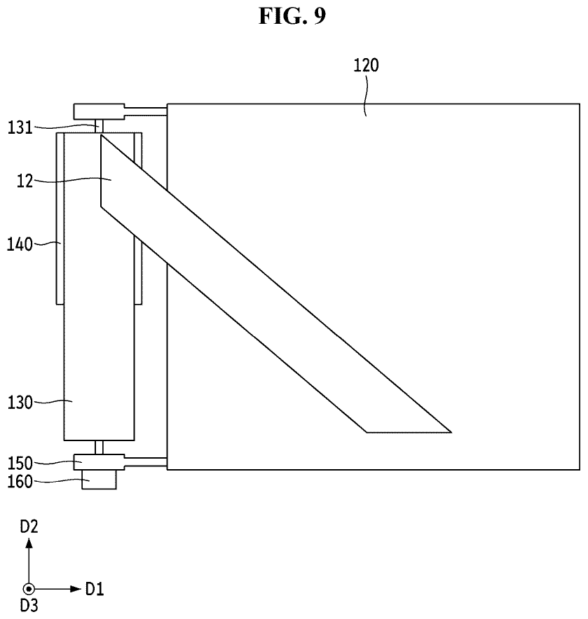

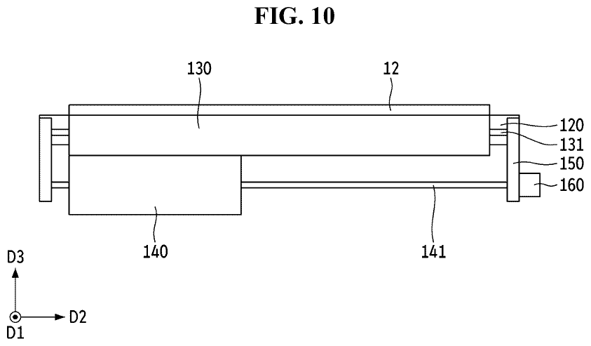

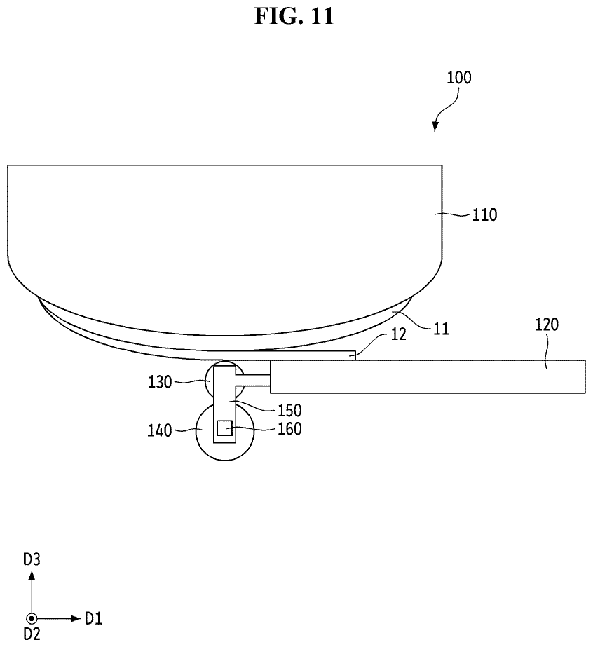

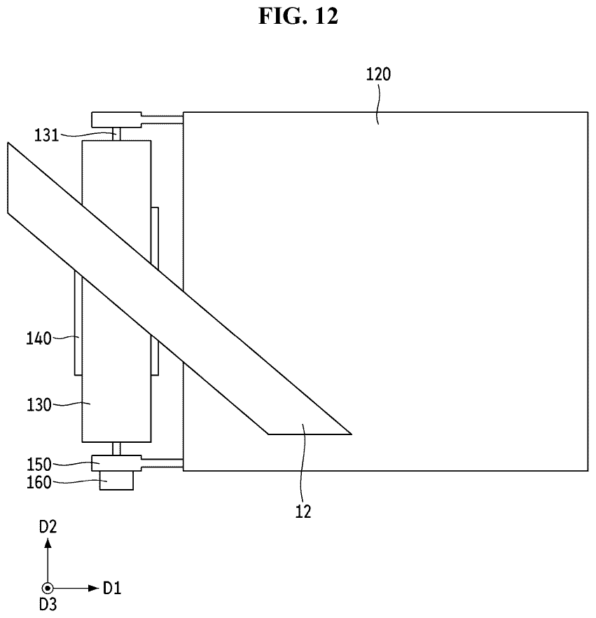

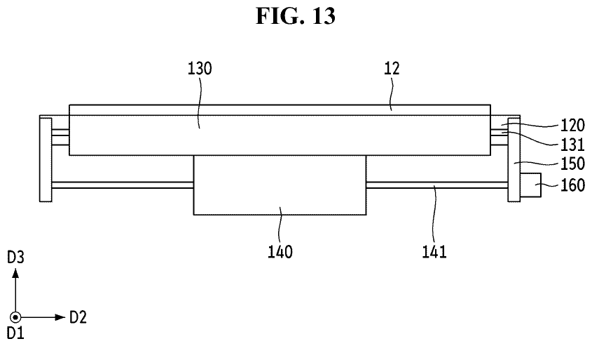

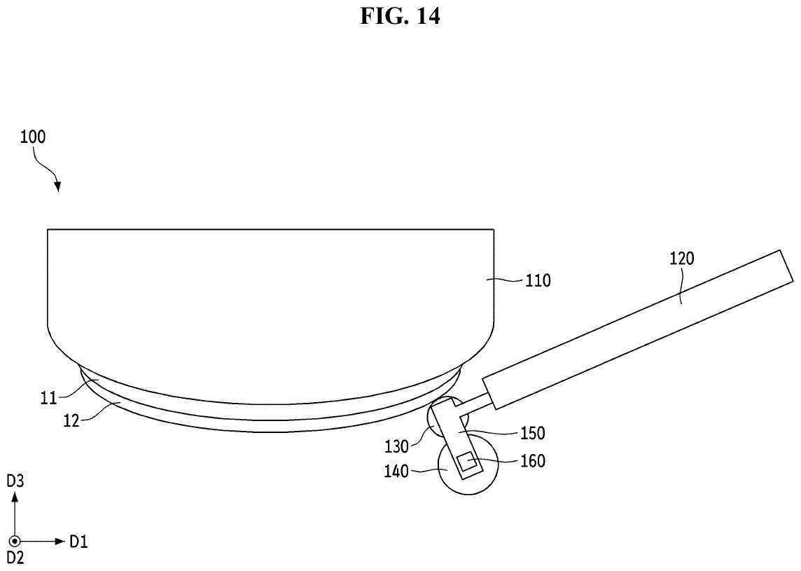

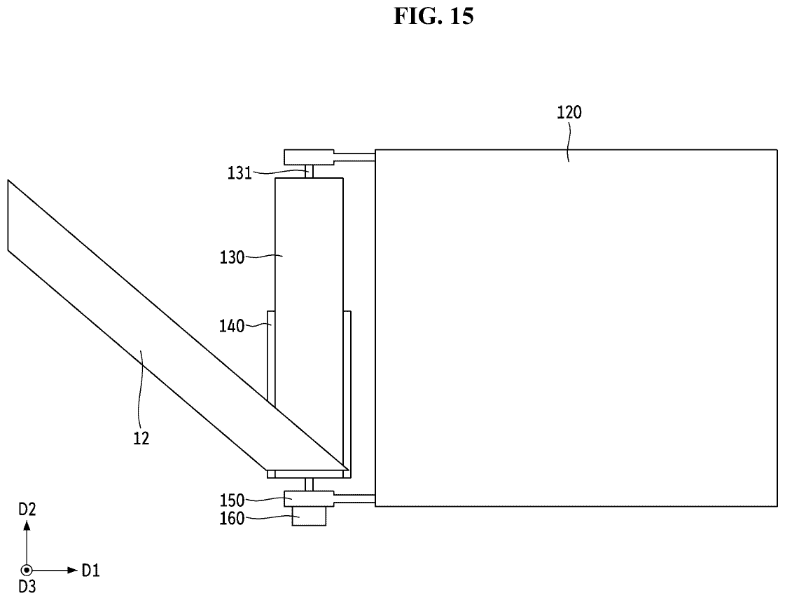

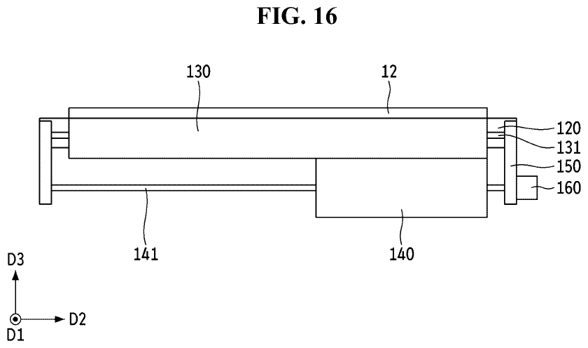

FIG. 8 is a schematic view illustrating an embodiment of a lamination apparatus according to the disclosure in a state that a cover window and a display panel start to be pressurized. FIG. 9 is a plan view illustrating a moving stage, a main roller, a guide roller, a support member, and a driving member of FIG. 8. FIG. 10 is a front view of FIG. 9. FIG. 11 is a schematic view illustrating an embodiment of a lamination apparatus according to the disclosure in a state that a cover window and a display panel are pressurized. FIG. 12 is a plan view illustrating a moving stage, a main roller, a guide roller, a support member, and a driving member of FIG. 11. FIG. 13 is a front view of FIG. 12. FIG. 14 is a schematic view illustrating an embodiment of a lamination apparatus according to the disclosure in a state that pressurization of a cover window and a display panel is terminated. FIG. 15 is a plan view illustrating a moving stage, a main roller, a guide roller, a support member, and a driving member of FIG. 14. FIG. 16 is a front view of FIG. 15.

The method for manufacturing the display device 10 in an embodiment of the disclosure may include an operation of arranging the cover window 11 on the fixed stage 110, an operation of arranging the display panel 12 on the upper surface of the moving stage 120 so that a portion of the display panel 12 is disposed on the main roller 130, an operation of arranging the moving stage 120 so that a portion of the display panel 12 disposed on the main roller 130 contacts the cover window 11, an operation of rotating the main roller 130 by movement of the moving stage 120 along the fixed stage 110 to pressurize the cover window 11 and the display panel 12, and an operation of moving the guide roller 140 in the longitudinal direction of the main roller 130.

In the operation of arranging the cover window 11 on the fixed stage 110, the cover window 11 may be disposed on one surface of the fixed stage 110, which is formed in a streamlined shape. One surface of the fixed stage 110, which is formed in a streamlined shape, may be formed in a lower area of the fixed stage 110.

In the operation of arranging the display panel 12 on the upper surface of the moving stage 120 so that a portion of the display panel 12 is disposed on the main roller 130, a portion of the display panel 12 may be disposed on the upper surface of the moving stage 120, and a remaining (the other) portion of the display panel 12 may be disposed on the upper surface of the moving stage 120. In an embodiment, when the display panel 12 has a polygonal planar shape including a plurality of sides, a portion of the display panel 12 disposed on the main roller 130 may be one of the plurality of sides of the display panel 12, for example. One side of the display panel 12 disposed on the main roller 130 may be disposed in parallel with the longitudinal direction of the main roller 130 (refer to FIG. 9). When a portion of the display panel 12 disposed on the main roller 130 is an edge portion of the display panel 12, an initial area in which the cover window 11 and the display panel 12 are pressurized is small, whereby poor bonding may occur between the cover window 11 and the display panel 12.

Referring to FIGS. 8 to 10, in the operation of arranging the moving stage 120 so that a portion of the display panel 12 disposed on the main roller 130 contacts the cover window 11, the moving stage 120 may be disposed below the fixed stage 110. The moving stage 120 may be disposed below the fixed stage 110 so that a portion of the display panel 12 disposed on the main roller 130 contacts one side (left side of FIG. 8) of the cover window 11 seated on the fixed stage 110. Since a portion of the display panel 12 disposed on the main roller 130 is disposed on one side (left side of FIG. 10) of the main roller 130, the guide roller 140 may be disposed below one side (left side of FIG. 10) of the main roller 130 to support the main roller 130.

Referring to FIGS. 11 to 13, in the operation of rotating the main roller 130 by movement of the moving stage 120 along the fixed stage 110 to pressurize the cover window 11 and the display panel 12, the moving stage 120 may move along one surface of the fixed stage 110, which is formed in a streamlined shape. Accordingly, the main roller 130 may rotate while moving along one surface of the fixed stage 110, which is formed in a streamlined shape. The main roller 130 that rotates by movement of the moving stage 120 may pressurize the display panel 12 onto the cover window 11 to bond the cover window 11 and the display panel 12 to each other. Since the display panel 12 disposed on the main roller 130 is disposed at a central portion of the main roller 130, the guide roller 140 may be disposed below the central portion of the main roller 130 to support the main roller 130 (refer to FIG. 13).

In the operation of moving the guide roller 140 in the longitudinal direction of the main roller 130, the guide roller 140 may move in the longitudinal direction of the main roller 130 to always overlap the display panel 12 pressurized against the cover window 11 by the main roller 130. The guide roller 140 may move by an operation of the driving member 160, and the driving member 160 may move the guide roller 140 at the same speed as the moving speed of the moving stage 120.

The diameter of the guide roller 140 may be larger than the diameter of the main roller 130. Since the guide roller 140 rotates by the rotation of the main roller 130 in contact with the main roller 130, when the diameter of the guide roller 140 is larger than the diameter of the main roller 130, the rotation speed of the guide roller 140 may be slower than the rotation speed of the main roller 130. When the rotation speed of the guide roller 140 is slower than the rotation speed of the main roller 130, the guide roller 140 may easily move, and may move more stably.

Referring to FIGS. 14 to 16, the moving stage 120 may continuously move along one surface of the fixing stage 110, which is formed in a streamlines shape, so that the main roller 130 may be disposed on an opposite side (right side of FIG. 14) of the cover window 11. While the main roller 130 is moving to an opposite side (right side of FIG. 14) of the cover window 11, the cover window 11 and the display panel 12 may be pressurized by the rotation of the main roller 130 so that the entirety of the cover window 11 and the entirety of the display panel 12 may be bonded to each other. Since the display panel 12 disposed on the main roller 130 is disposed on an opposite side (right side of FIG. 16), the guide roller 140 may be disposed below an opposite side (right side of FIG. 16) of the main roller 130 to support the main roller 130.

The display device manufactured using the lamination apparatus 100 in an embodiment of the disclosure may be applied to various electronic devices. The electronic device in an embodiment includes the above-described display device, and may further include modules or devices, which have other additional functions, in addition to the display device.

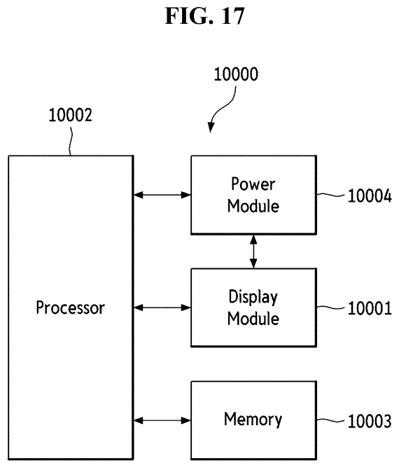

FIG. 17 is a block diagram illustrating an embodiment of an electronic device.

Referring to FIG. 17, an electronic device 10000 in an embodiment may include a display module 10001, a processor 10002, a memory 10003, and a power module 10004.

The processor 10002 may include at least one of a central processing unit (“CPU”), an application processor (“AP”), a graphic processing unit (“GPU”), a communication processor (“CP”), an image signal processor (“ISP”), or a controller.

Data information desired for an operation of the processor 10002 or the display module 10001 may be stored in the memory 10003. When the processor 10002 executes an application stored in the memory 10003, an image data signal and/or an input control signal is transmitted to the display module 10001, and the display module 10001 may process the received signal and output image information through a display screen.

The power module 10004 may include a power supply module such as a power adapter or a battery device, and a power conversion module that converts a power source supplied by the power supply module to generate a power source desired for the operation of the electronic device 10000.

At least one of the respective components of the above-described electronic device 10000 may be included in the display device according to the above-described embodiments. Also, some of the individual modules functionally included in one module may be included in the display device, and others thereof may be provided separately from the display device. In an embodiment, the display device includes the display module 10001, and the processor 10002, the memory 10003 and the power module 10004 may be provided as other devices in the electronic device 10000 not the display device, for example.

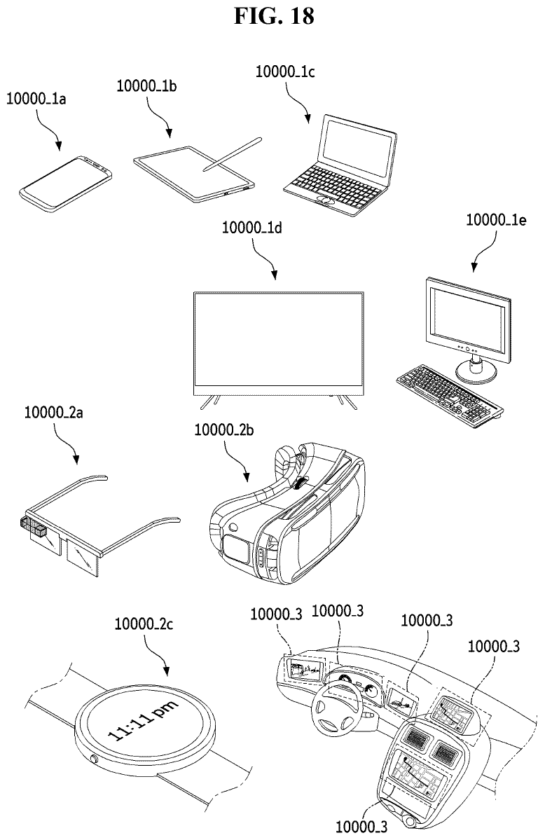

FIG. 18 illustrates schematic diagrams of embodiments of electronic devices.

Referring to FIG. 18, various electronic devices to which the display devices in the embodiments are applied may include not only electronic devices for image display, such as a smart phone 10000_1a, a tablet personal computer (“PC”) 10000_1b, a laptop 10000_1c, a television (“TV”) 10000_1d, and a desk monitor 10000_1e, but also wearable electronic devices including display modules such as smart glasses 10000_2a, a head mounted display 10000_2b, and a smart watch 10000_2c, a vehicle electronic device 10000_3 including display modules such as a vehicle dashboard, a center fascia, a center information display (“CID”) arranged on the dashboard, and a room mirror display.

It should be understood, however, that the advantages and features of embodiments of the disclosure are not restricted to the one set forth herein. The above and other features of the disclosure will become more apparent to one of ordinary skill in the art to which the disclosure pertains by referencing the claims, with equivalents thereof to be included therein.

What is claimed is:

1. A lamination apparatus comprising:
a fixed stage which supports a cover window;
a moving stage which supports a display panel and moves along the fixed stage;
a main roller which is connected to the moving stage, rotates in accordance with the movement of the moving stage and pressurizes the display panel against the cover window; and
a guide roller which rotates in accordance with the rotation of the main roller in contact with at least a portion of the main roller, and moves in a longitudinal direction of the main roller.

2. The lamination apparatus of claim 1, further comprising:
a support member which is connected to the moving stage, and rotatably supports a rotation shaft of the main roller and a rotation shaft of the guide roller; and
a driving member which moves the guide roller.

3. The lamination apparatus of claim 2, wherein the rotation shaft of the main roller and the rotation shaft of the guide roller are parallel with each other.

4. The lamination apparatus of claim 2, wherein the driving member moves the guide roller along the rotation shaft of the guide roller.

5. The lamination apparatus of claim 1, wherein a moving speed of the guide roller is equal to a moving speed of the moving stage.

6. The lamination apparatus of claim 1, wherein, when the display panel rotates in a horizontal direction in a state of being supported by the moving stage, all areas of the display panel are arranged on the moving stage.

7. The lamination apparatus of claim 1, wherein a length of the guide roller is shorter than a length of the main roller.

8. The lamination apparatus of claim 1, wherein a diameter of the main roller is less than a diameter of the guide roller.

9. The lamination apparatus of claim 1, wherein the guide roller moves along the longitudinal direction of the main roller to overlap the display panel pressurized against the cover window by the main roller.

10. The lamination apparatus of claim 1, wherein an upper end of an outer circumference of the main roller and an upper surface of the moving stage are disposed on a same virtual plane.

11. The lamination apparatus of claim 1, wherein a rotation speed of the main roller is faster than a rotation speed of the guide roller.

12. A method for manufacturing a display device, the method comprising:
arranging a cover window on a fixed stage;
arranging a display panel on an upper surface of a moving stage so that a portion of the display panel is disposed on a main roller,
arranging the moving stage so that a portion of the display panel disposed on the main roller contacts the cover window;
rotating the main roller by movement of the moving stage along the fixed stage to pressurize the cover window and the display panel; and
moving a guide roller in a longitudinal direction of the main roller.

13. The method of claim 12, wherein the display panel includes a plurality of sides, and
when arranging the display panel on the upper surface of the moving stage so that a portion of the display panel is disposed on the main roller, a portion of the display panel disposed on the main roller is one of the plurality of sides of the display panel.

14. The method of claim 13, wherein one side of the display panel disposed on the main roller is disposed to be parallel with the longitudinal direction of the main roller.

15. The method of claim 12, wherein a moving speed of the guide roller is equal to a moving speed of the moving stage.

16. The method of claim 12, wherein the guide roller rotates in accordance with the rotation of the main roller in contact with at least a portion of the main roller, and
a rotation speed of the main roller is faster than a rotation speed of the guide roller.

17. The method of claim 12, wherein a diameter of the main roller is less than a diameter of the guide roller.

18. The method of claim 12, wherein the moving the guide roller in the longitudinal direction of the main roller includes moving the guide roller along the longitudinal direction of the main roller to overlap the display panel pressurized against the cover window by the main roller.

19. An electronic device comprising:
a display device manufactured by a lamination apparatus, the lamination apparatus comprising:
a fixed stage which supports a cover window;
a moving stage which supports a display panel and moves along the fixed stage;
a main roller which is connected to the moving stage, rotates in accordance with the movement of the moving stage and pressurizes the display panel against the cover window; and
a guide roller which rotates in accordance with the rotation of the main roller in contact with at least a portion of the main roller, and moves in a longitudinal direction of the main roller.

20. The electronic device of claim 19, further comprising at least one of:
a processor;
a memory in which one or more data of the display device and the processor are stored; or
a power module which supplies a power source to the display device, the processor, and the memory.
